(19) United States
(12) Patent Application Publication
(10) Pub. No.: US 2009/0073670 A1
(43) Pub. Date: Mar. 19, 2009

(54) Multilayered printed circuit board and fabricating method thereof

(75) Inventors: Jong-Kuk Hong, Suwon-si (KR); Jin-Yong An, Daejeon (KR); Jae-Joon Lee, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/076,358

(22) Filed: Mar. 17, 2008

(30) Foreign Application Priority Data
Sep. 18, 2007 (KR) 10-2007-0094917

(51) Int. Cl. H05K 1/14; H05K 3/10; H05K 3/36; H05K 3/42

(52) U.S. Cl. 361/792; 361/795; 29/830; 29/852

(57) ABSTRACT

A multilayered printed circuit board and a fabricating method thereof are disclosed. A method that includes repeating processes of forming at least one circuit pattern, and at least one insulation layer that covers the circuit pattern, over a carrier and interconnecting circuit patterns on different layers with vias; stacking a metal stiffener over the insulation layer; repeating processes of forming at least one insulation layer and at least one circuit pattern over the stiffener and interconnecting circuit patterns on different layers with vias; and removing the carrier, can be used to reduce warpage in the board and improve workability.

### CROSS-REFERENCE TO RELATED APPLICATIONS

This application claims the benefit of Korean Patent Application No. 10-2007-0094917 filed with the Korean Intellectual Property Office on Sep. 18, 2007, the disclosure of which is incorporated herein by reference in its entirety.

### BACKGROUND

1. Technical Field

The present invention relates to a multilayered printed circuit board and to a method of fabricating the multilayered printed circuit board.

2. Description of the Related Art

As current electronic products trend towards smaller, thinner, higher-density, and packaged products, so also is the multilayered printed circuit board undergoing a trend towards finer patterns and smaller and packaged products. Accordingly, the layer construction is being implemented in greater complexity, in order to provide finer circuit patterns, enhanced reliability, and increased design density, while the components are also undergoing a change from DIP (dual in-line package) types to SMT (surface mount technology) types. Some of the major tasks involved in the fabrication of these multilayered printed circuit boards that are produced in higher densities and lower thicknesses, may include resolving the problem of warpage in the boards and increasing workability in the fabricating process.

### SUMMARY

An aspect of the invention is to provide a multilayered printed circuit board and a method of fabricating the multilayered printed circuit board, which can prevent warpage in the board, and which allows high workability.

One aspect of the invention provides a multilayered printed circuit board that includes: a circuit pattern positioned on each layer of the printed circuit board; a plurality of insulation layers formed over the circuit patterns; a via hole that interconnect circuit patterns positioned on different insulation layers; and a metal stiffener formed on the insulation layer, where an opening is formed in the stiffener, through which the via hole passes.

Embodiments of the multilayered printed circuit board according to an aspect of the invention may include one or more of the following features. For example, the circuit patterns and the insulation layers may be formed substantially symmetrically about the stiffener, and multiple stiffeners may be formed. The stiffener can be made from any one of aluminum, copper, and nickel, and can have a thickness of 40 μm or lower.

Another aspect of the invention provides a method of fabricating a multilayered printed circuit board. The method includes: repeating processes of forming at least one circuit pattern, and at least one insulation layer that covers the circuit pattern, over a carrier and interconnecting circuit patterns on different layers with vias; stacking a metal stiffener over the insulation layer; repeating processes of forming at least one insulation layer and at least one circuit pattern over the stiffener and interconnecting circuit patterns on different layers with vias; and removing the carrier.

Embodiments of the method for fabricating a multilayered printed circuit board according to an aspect of the invention may include one or more of the following features. For example, the circuit patterns and the insulation layers may be formed substantially symmetrically about the stiffener, and multiple stiffeners may be formed. The method may further include forming at least one opening in the stiffener, through which the via hole may pass, after the operation of stacking the stiffener. The method may also include removing at least one portion of the stiffener in correspondence to at least one position where routing is to be performed for the multilayered printed circuit board, after the operation of stacking the stiffener. The stiffener can be made from any one of aluminum, copper, and nickel, and can have a thickness of 40 μm or lower.

The circuit patterns and the insulation layers may be formed on both sides of the carrier.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of fabricating a multilayered printed circuit board according to an embodiment of the invention.

FIG. 2 is a cross-sectional view illustrating a circuit pattern formed on a carrier, in the method of fabricating a multilayered printed circuit board according to an embodiment of the invention.

FIG. 3 is a cross-sectional view after stacking an insulation layer over the circuit pattern, in the method of fabricating a multilayered printed circuit board according to an embodiment of the invention.

FIG. 4 is a cross-sectional view after forming via holes in the insulation layer, in the method of fabricating a multilayered printed circuit board according to an embodiment of the invention.

FIG. 5 is a cross-sectional view after forming a circuit pattern and filling the via holes, in the method of fabricating a multilayered printed circuit board according to an embodiment of the invention.

FIG. 6 is a cross-sectional view after stacking a stiffener on the insulation layer, in the method of fabricating a multilayered printed circuit board according to an embodiment of the invention.

FIG. 7 is a cross-sectional view after forming an opening in the stiffener, in the method of fabricating a multilayered printed circuit board according to an embodiment of the invention.

FIG. 8 is a cross-sectional view after stacking an insulation layer on the stiffener, in the method of fabricating a multilayered printed circuit board according to an embodiment of the invention.

FIG. 9 is a cross-sectional view after forming a via hole for interconnecting layers in the insulation layer, in the method of fabricating a multilayered printed circuit board according to an embodiment of the invention.

FIG. 10 is a cross-sectional view after forming a circuit pattern and filling the via hole, in the method of fabricating a multilayered printed circuit board according to an embodiment of the invention.

FIG. 11 is a cross-sectional view after stacking an insulation layer and forming a circuit pattern, in the method of fabricating a multilayered printed circuit board according to an embodiment of the invention.

FIG. 12 is a cross-sectional view after removing the carrier and forming solder resists, in the method of fabricating a multilayered printed circuit board according to an embodiment of the invention.

FIG. 13 is a cross-sectional view of a multilayered printed circuit board according to another embodiment of the invention.

FIG. 14 is a cross-sectional view of a multilayered printed circuit board according to yet another embodiment of the invention.

FIG. 15 is a cross-sectional view illustrating multilayered printed circuit boards formed on both sides of a carrier.

### DETAILED DESCRIPTION

As the invention allows for various changes and numerous embodiments, particular embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

The terms used in the present application are merely used to describe particular embodiments, and are not intended to limit the present invention. An expression used in the singular encompasses the expression of the plural, unless it has a clearly different meaning in the context. In the present application, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

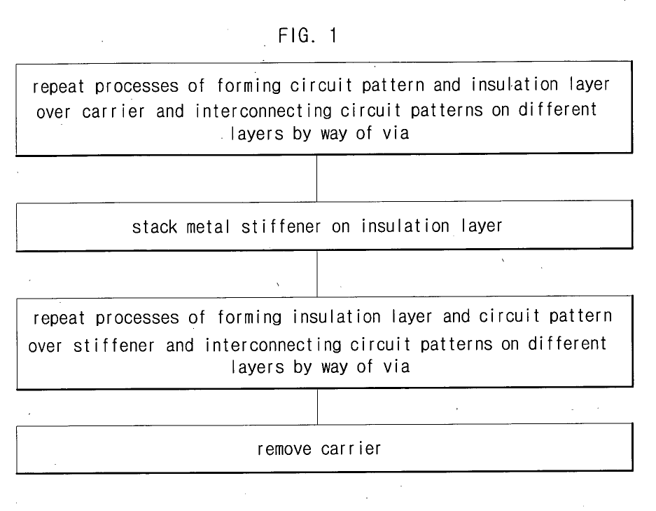

FIG. 1 is a flowchart illustrating a method of fabricating a multilayered printed circuit board according to an embodiment of the invention.

Referring to FIG. 1, a method of fabricating a multilayered printed circuit board according to an embodiment of the invention may include: forming a circuit pattern on a carrier and stacking an insulation layer over the circuit pattern and then forming a via hole, filling the via hole and forming a circuit pattern over the insulation layer, repeating the operations for stacking an insulation layer over the circuit pattern and forming a via hole and filling the via hole, stacking a stiffener over the insulation layer, repeating the operations for stacking an insulation layer over the stiffener and forming a via hole and filling the via hole, and removing the carrier.

As such, in a method of fabricating a multilayered printed circuit board according to an embodiment of the invention, a rigid stiffener may be inserted inside the printed circuit board, which can help to not only prevent warpage in the printed circuit board but also keep the overall thickness of the board low. Since the stiffener can be stacked in any layer of the printed circuit board, a board structure can be obtained that is more resistant to thermal impact, by performing analysis, such as on thermal stress, etc., when mounting a semiconductor component, etc., onto the board. Also, as the multilayered printed circuit board according to this embodiment employs a carrier, which is subsequently detached and removed, a greater degree of workability can be provided.

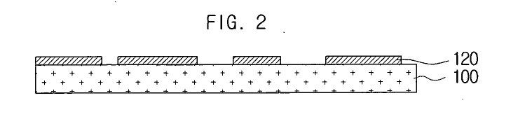

The following will describe a method of fabricating a multilayered printed circuit board according to an embodiment of the invention in further detail, with reference to FIG. 2 through FIG. 12.

FIG. 2 is a cross-sectional view illustrating a circuit pattern 120 formed on a carrier 100, in the method of fabricating a multilayered printed circuit board according to an embodiment of the invention.

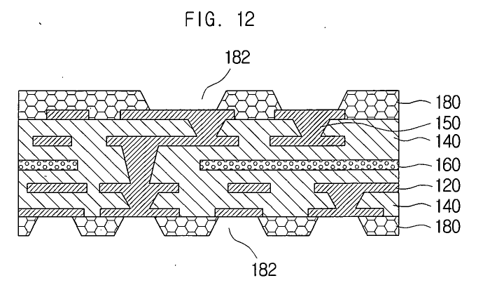

The carrier 100 may have a level of stiffness, and may be used to increase the overall workability of the printed circuit board. That is, the low thickness of the multilayered printed circuit board based on this embodiment can pose problems in workability, but as the carrier 100 can provide rigidity to the printed circuit board, the workability may be increased. The carrier 100 can be formed from a metal or synthetic plastic, etc., having rigidity. For example, the carrier 100 can be made from metal, such as aluminum, copper, and nickel, etc. The carrier 100 can be removed in a subsequent process (see FIG. 12).

The circuit pattern 120 formed on the carrier 100 can be formed by a general method such as copper plating and inkjet printing. In a subsequent process, an insulation layer 140 may be stacked over the circuit pattern 120, where the insulation layer 140 may completely cover the circuit pattern 120, so that the circuit pattern 120 may not be exposed to the exterior.

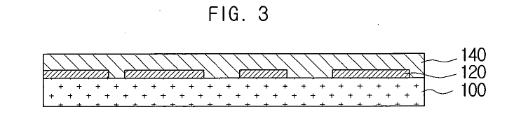

FIG. 3 is a cross-sectional view after stacking an insulation layer 140 over the carrier 100 in FIG. 2 and performing leveling.

Referring to FIG. 3, the insulation layer 140 may be stacked on the carrier 100, to completely cover the circuit pattern 120 formed over the carrier 100. The insulation layer 140 can be made from a thermosetting resin, thermoplastic resin, UV-setting resin, and/or unsaturated-group-containing resin by itself or in a combination of two or more types. In certain cases, a thermosetting resin composition or a heat-resistant thermoplastic resin composition having a melting point of 270° C. or higher can be used.

The thermosetting resin used for the insulation layer of the insulation layer 140 can be such that is generally known to those skilled in the art. For example, an epoxy resin, cyanate ester resin, bismaleimide resin, polyimide resin, functional-group-containing polyphenylene ether resin, cardo resin, or phenol resin, etc., which are resins known to those skilled in the art, can be used by itself or in a combination of two or more resins. In certain cases, cyanate ester resin may be used to prevent migration between through-holes or between circuits, which are constantly getting narrower. The known resins described above may be used after applying flame-retardant treatment with phosphorus.

While a thermosetting resin according to this embodiment can be hardened by heating the resin as is, this may entail a slow hardening rate and low productivity. Thus, an adequate amount of hardening agent or thermosetting catalyst may be used in the thermosetting resin.

Various other additives may generally be used in the thermosetting resin. For example, a thermosetting resin, a thermoplastic resin, or another type of resin may be added, other than the main resin used, as well as adequate amounts of an organic or inorganic filler, a dye, pigments, a thickening agent, lubricant, an antifoaming agent, a dispersing agent, leveling agent, brightening agent, and thixotropic agent, etc., according to the purpose and usage of the composition. It is also possible to use a flame retardant, such as those using phosphorus and bromine, and non-halogenated types.

The thermoplastic resin used can be such that is generally known to those skilled in the art. More specifically, liquid crystal polyester resin, polyurethane resin, polyamide resin, polyphenylene ether resin, etc. can be used by itself or in a combination of two or more resins. The thermoplastic that is used can have a melting point of 270° C. or higher, so that there may be no defects in the wiring board during the reflow treatment process, which is performed under high temperatures. The various additives described above may also be added in adequate amounts to the thermoplastic resin. Furthermore, a thermoplastic resin and a thermosetting resin can be used together as a mixture.

Besides the thermosetting resin and thermoplastic resin, other resins may be used alone or in combination, such as UV-setting resins and rapid setting resins, etc. Also, a photopolymerization initiator, radical polymerization initiator, and/or the various additives described above can be mixed in in adequate amounts.

After stacking the insulation layer 140 on the carrier 100, the thickness of the insulation layer 140 can be made uniform by performing a leveling process. A circuit pattern 120 may be formed on the insulation layer 140, whereby the insulation layer 140 may serve to insulate the circuit patterns 120 formed on different layers.

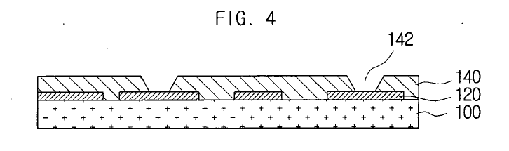

FIG. 4 is a cross-sectional view after forming via holes 142 in the insulation layer 140.

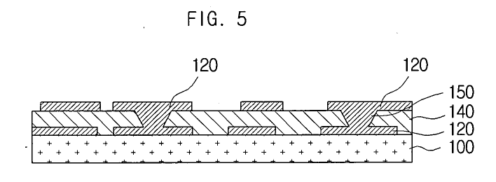

Referring to FIG. 4, via holes 142 may be formed, in order to form vias 150 (FIG. 5) that interconnect the circuit pattern 120 positioned on the carrier 100 and the circuit pattern 120 positioned on the insulation layer 140. The method of forming the via holes 142 may include mechanical drilling or laser drilling, etc. The via holes 142 may also be formed chemically, by using an etchant such as ferric chloride, etc. Due to the forming of the via holes 142, the circuit pattern 120 formed over the carrier 100 can be exposed to the exterior through the via holes 142.

FIG. 5 is a cross-sectional view after forming another circuit pattern 150 over the insulation layer 140.

Referring to FIG. 5, a circuit pattern 120 may be formed, while filling the via holes 142 formed in the insulation layer 140 with a copper plating. Typical methods known to those skilled in the art can be used for the forming of the circuit pattern 120 and the filling of the via hole 142, which in certain cases may include semi-additive processes. Filling the via holes 142 may result in via 150 being formed. The vias 150 may serve to interconnect the circuit pattern 120 formed on the carrier 100 and the circuit pattern 120 formed on the insulation layer 140.

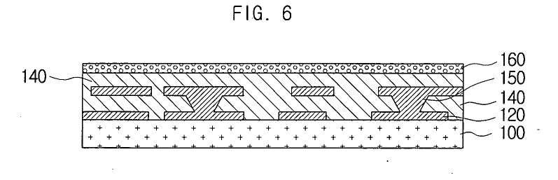

FIG. 6 is a cross-sectional view after stacking an insulation layer 140 over the circuit pattern 120 in FIG. 5 and then forming a stiffener 160 over the insulation layer 140.

Referring to FIG. 6, an insulation layer 140 may be stacked again over the circuit pattern 120 formed in FIG. 5, and a stiffener 160 may be formed over the insulation layer 140. The stiffener 160 can be made of metal, such as aluminum, nickel, and copper, etc., and can have a certain degree of stiffness, to prevent bending and warpage in the printed circuit board. The method of forming the stiffener 160 can include plating processes, as well as methods of stacking on a metal foil that has a uniform thickness, etc. In order that the printed circuit board may not be given an excessive overall thickness, the stiffener 160 can have a thickness of 40 μm or lower.

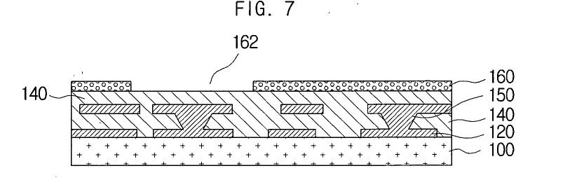

FIG. 7 is a cross-sectional view after forming an opening 162 in the stiffener 160 formed in FIG. 6.

Referring to FIG. 7, a portion of the stiffener 160 corresponding to where a via hole is to be formed in a subsequent process may be severed, to form an opening 162. Thus, the subsequent via-forming process can be facilitated. Methods for forming the opening 162 may include chemical etching, etc. Although it is not illustrated in the drawings, if the stiffener 160 is made from a material high in rigidity, the stiffener 160 can cause problems in routing, etc., after the printed circuit board is fabricated. As such, when forming the opening 162, the routing paths can be formed at the same time.

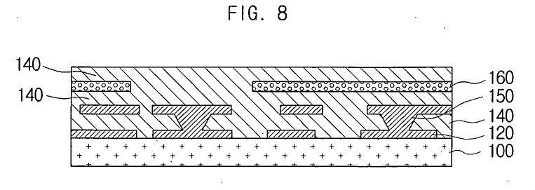

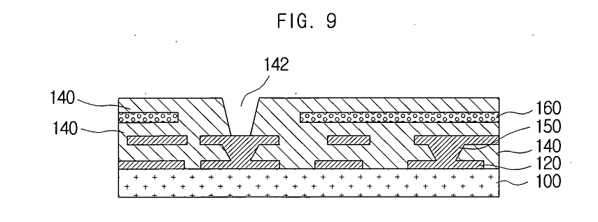

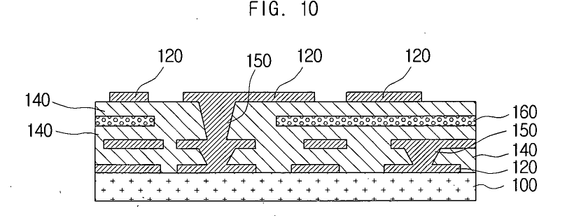

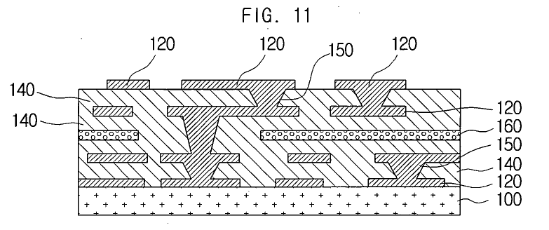

FIG. 8 is a cross-sectional view after forming an insulation layer 140 over the stiffener 160 in FIG. 7, and FIG. 9 is a cross-sectional view after forming a via hole 142 in the insulation layer 140 formed in FIG. 8, while FIG. 10 is a cross-sectional view after forming a circuit pattern 120 over the insulation layer 140 formed in FIG. 9 and filling the via hole 142. FIG. 11 is a cross-sectional view after performing these processes again over the circuit pattern 120 formed in FIG. 10 to form one more layer of insulation layer 140 and circuit pattern 120.

Referring to FIG. 11, the insulation layers 140 and circuit patterns 120 can be formed in substantial symmetry, with respect to the stiffener 160. The circuit pattern 120 on each layer can be interconnected by vias 150. While FIG. 11 illustrates an example in which two layers of circuit patterns 120 are formed above the stiffener 160 and two layers of circuit patterns 120 are formed below the stiffener 160, the invention is not thus limited. For example, three or more layers of circuit patterns 120 may be stacked about the stiffener 160, and the circuit patterns 120 may be positioned in various locations other than the middle of the printed circuit board.

FIG. 12 is a cross-sectional view after removing the carrier 100 in FIG. 11 and stacking a solder resist 180 on either outer side of the printed circuit board.

Referring to FIG. 12, after the forming of the circuit pattern 120 is complete, the carrier 100 can be detached, and solder resists 180 may be stacked on either outer side of the printed circuit board, in preparation for a subsequent process. Even after the carrier 100 is removed, the printed circuit board thus formed may have a constant thickness, and may not pose problems in proceeding with the fabrication process.

As described above, a method of fabricating a printed circuit board according to this embodiment, as well as the printed circuit board thus produced, employs a carrier to increase workability, which is subsequently removed to provide a low thickness for the printed circuit board. The problems of warpage or bending, etc., that can occur in a thin printed circuit board may be resolved by the stiffener 160 positioned within the board, whereby a board can be implemented to have a low thickness as well as high rigidity. Furthermore, as described below, multiple stiffeners can be positioned in certain layers of the board, making it possible to implement a board structure that is stronger with respect to thermal impacts, based on thermal stress analysis, etc., when mounting the stiffeners.

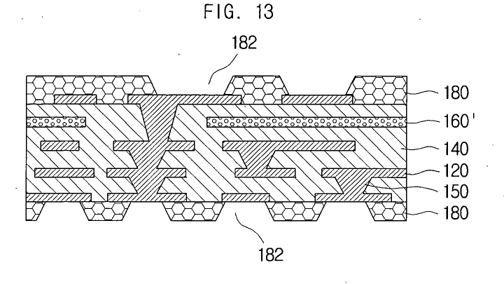

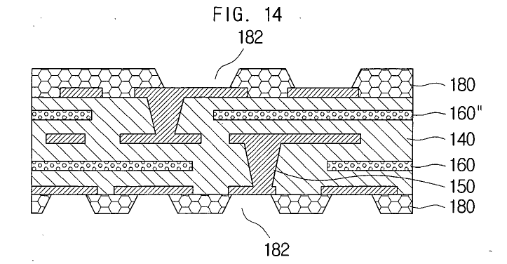

FIG. 13 is a cross-sectional view of a multilayered printed circuit board according to another embodiment of the invention, in which the stiffener 160′ is eccentric to one side from the center of the board. FIG. 14 is a cross-sectional view of a multilayered printed circuit board according to yet another embodiment of the invention, in which multiple stiffeners 160″ are formed.

FIG. 13 illustrates a stiffener 160′ located in a position other than the center of the board, and FIG. 14 illustrates more than one stiffeners 160″ located in certain positions of the board. As observed in FIGS. 13 and 14, in the multilayered printed circuit board according to embodiments of the invention, the position and number of the stiffener can be varied, whereby it is possible to implement a board structure that is stronger with respect to thermal impacts, based on thermal stress analysis, etc., when mounting stiffeners and/or chips.

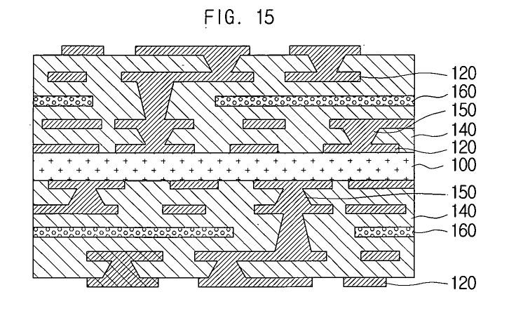

FIG. 15 is a cross-sectional view illustrating multilayered printed circuit boards formed on both sides of a carrier 100, in a method of fabricating a multilayered printed circuit board according to yet another embodiment of the invention.

Referring to FIG. 15, while it is possible to use just one side of the carrier 100, it is also possible to use both sides of the carrier 100 to form multilayered printed circuit boards. Forming the multilayered printed circuit board on either side of the carrier 100 can be achieved by proceeding with the fabrication process described with reference to FIGS. 2 to 11, at the same time on both sides of the carrier 100. When the multilayered printed circuit boards are completed, the boards may be detached from the carrier 100, after which solder resists may be formed on each of the detached multilayered printed circuit board, as illustrated in FIG. 12.

The following presents a comparison between examples of multilayered printed circuit boards based on embodiments of the invention and a comparative example of a conventional multilayered printed circuit board, to further elaborate on the composition and advantages of particular embodiments of the invention.

### EXAMPLE 1

For Example 1, a 10 μm thick stiffener made of nickel was placed in the center of a board having longitudinal and lateral dimensions of 20 mm each, and three layers of insulation layers and three layers of circuit patterns were formed respectively above and below the stiffener. Solder resists were formed to a 20 μm thickness on the outermost circuit patterns and insulation layers. The thickness of each circuit pattern and insulation layer is listed below in Table 1. The percentage of space occupied by the circuit pattern in each layer is listed below in Table 2.

### EXAMPLE 2

For Example 2, a 20 μm thick stiffener made of nickel was placed in the center of a board having longitudinal and lateral dimensions of 20 mm each, and three layers of insulation layers and three layers of circuit patterns were formed respectively above and below the stiffener. Solder resists were formed to a 20 μm thickness on the outermost circuit patterns and insulation layers. The thickness of each circuit pattern and insulation layer is listed below in Table 1. The percentage of space occupied by the circuit pattern in each layer is listed below in Table 2.

### COMPARATIVE EXAMPLE

In the Comparative Example, a stiffener was not placed in the center of a board having longitudinal and lateral dimensions of 20 mm each, and six layers of insulation layers and six layers of circuit patterns were formed continuously. Solder resists were formed to a 20 μm thickness on the outermost circuit patterns and insulation layers. The thickness of each circuit pattern and insulation layer is listed below in Table 1. The percentage of space occupied by the circuit pattern in each layer is listed below in Table 2.

TABLE 1
Thickness of Insulation Layers and Circuit Patterns for Each Layer

| | | | Comparative |
|---|---|---|---|
| | Example 1 | Example 2 | Example |
| Solder Resist | 20 μm | 20 μm | 20 μm |
| Circuit Pattern, 3rd Upper Layer | 15 μm | 15 μm | 15 μm |
| Insulation Layer | 30 μm | 30 μm | 30 μm |
| Circuit Pattern, 2nd Upper Layer | 15 μm | 15 μm | 15 μm |
| Insulation Layer | 30 μm | 30 μm | 30 μm |
| Circuit Pattern, 1st Upper Layer | 15 μm | 15 μm | 15 μm |
| Insulation Layer | 15 μm | 15 μm | 15 μm |
| Stiffener (Nickel) | 10 μm | 20 μm | 0 μm |
| Insulation Layer | 15 μm | 15 μm | 15 μm |
| Circuit Pattern, 1st Lower Layer | 15 μm | 15 μm | 15 μm |
| Insulation Layer | 30 μm | 30 μm | 30 μm |
| Circuit Pattern, 2nd Lower Layer | 15 μm | 15 μm | 15 μm |
| Insulation Layer | 30 μm | 30 μm | 30 μm |
| Circuit Pattern, 3rd Lower Layer | 15 μm | 15 μm | 15 μm |
| Solder Resist | 20 μm | 20 μm | 20 μm |
| Overall Thickness | 290 μm | 300 μm | 280 μm |

TABLE 2
Percentage of Circuit Pattern (Copper) in Each Layer

| | Layer | | | | | |
|---|---|---|---|---|---|---|
| | 1st Upper | 1st Lower | 2nd Upper | 2nd Lower | 3rd Upper | 3rd Lower |
| Percentage of | 86% | 86% | 89% | 92% | 50% | 71% |
| Copper Pattern | | | | | | |

As shown in the above Tables 1 and 2, the overall size of the printed circuit board, the thickness and composition of each layer, and the percentage occupied by a copper circuit pattern in each layer are substantially the same for Example 1, Example 2, and the Comparative Example. The only difference is in the thickness of the stiffener located in the center of the printed circuit board, which makes the overall thicknesses 290 μm, 300 μm, and 280 μm, respectively.

Under these conditions, the degree of warpage occurring in each printed circuit board was measured and listed below in Table 3, for Example 1, Example 2, and the Comparative Example.

TABLE 3
Degree of Warpage in Each Printed Circuit Board

| | Example 1 | Example 2 | Comparative Example |
|---|---|---|---|
| Warpage | 92 μm | 83 μm | 104 μm |

As observed in Table 3, Example 1, which has a 10 μm thick stiffener in the center of the printed circuit board, shows about a 12% decrease in the degree of warpage compared to the Comparative Example, while Example 2 shows about a 20% decrease.

The results of the measurements show that by stacking a stiffener made of metal in the middle of a printed circuit board, the degree of warpage in the overall board can be reduced, and that the thicker the stiffener, the more the degree of warpage reduced.

As set forth above, certain aspects of the invention provide a multilayered printed circuit board and a fabricating method for the multilayered printed circuit board, which can prevent warpage in the board and provide high workability.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A multilayered printed circuit board comprising:
a circuit pattern positioned on each layer of the printed circuit board;
a plurality of insulation layers formed over the circuit patterns;
a via hole interconnecting the circuit patterns positioned on different insulation layers; and
a metal stiffener formed on the insulation layer,
wherein the stiffener has an opening formed therein, the opening having the via hole pass therethrough.

2. The multilayered printed circuit board of claim 1, wherein the circuit patterns and the insulation layers are formed substantially symmetrically about the stiffener.

3. The multilayered printed circuit board of claim 1, wherein the stiffener is formed in a plurality.

4. The multilayered printed circuit board of claim 1, wherein the stiffener includes any one of aluminum, copper, and nickel.

5. The multilayered printed circuit board of claim 4, wherein a thickness of the stiffener is 40 μm or lower.

6. A method of fabricating a multilayered printed circuit board, the method comprising:
repeating processes of forming over a carrier at least one circuit pattern and at least one insulation layer covering the circuit pattern, and interconnecting the circuit patterns on different layers by way of vias;
stacking a metal stiffener on the insulation layer;
repeating processes of forming over the stiffener at least one insulation layer and at least one circuit pattern and interconnecting the circuit patterns on different layers by way of vias; and
removing the carrier.

7. The method of claim 6, wherein the insulation layers are formed substantially symmetrically about the stiffener.

8. The method of claim 6, wherein the stiffener is formed in a plurality.

9. The method of claim 6, comprising, after stacking the stiffener:
forming at least one opening in the stiffener, the opening having the via hole pass therethrough.

10. The method of claim 6, comprising, after stacking the stiffener:
removing at least one portion of the stiffener in correspondence to at least one position where routing is performed for the multilayered printed circuit board.

11. The method of claim 6, wherein the stiffener includes any one of aluminum, copper, and nickel.

12. The method of claim 6, wherein a thickness of the stiffener is 40 μm or lower.

13. The method of claim 6, wherein the circuit patterns and the insulation layers are formed on both sides of the carrier.
